(19) United States
(12) Patent Application Publication
(10) Pub. No.: US 2021/0171549 A1
(43) Pub. Date: Jun. 10, 2021

(54) SURFACE TREATMENT AGENT AND SURFACE TREATMENT METHOD

(71) Applicant: TOKYO OHKA KOGYO CO., LTD., Kawasaki-shi (JP)

(72) Inventors: Makoto SATO, Kawasaki-shi (JP); Natsumi OKAWA, Kawasaki-shi (JP); Issei SUZUKI, Kawasaki-shi (JP); Emi TAKAHASHI, Kawasaki-shi (JP)

(21) Appl. No.: 17/108,638

(22) Filed: Dec. 1, 2020

(30) Foreign Application Priority Data
Dec. 6, 2019 (JP) 2019-221093

(51) Int. Cl. C07F 7/10; C09D 5/00; H01L 21/02

(52) U.S. Cl. CPC C07F 7/10; H01L 21/02282; H01L 21/02219; C09D 5/00

(57) ABSTRACT

A surface treatment agent including a silylating agent and a solvent, the silylating agent including a compound represented by General Formula (A-1) in which Ra¹ is a monovalent organic group or a hydrogen atom; Ra² is a monovalent organic group; a Si atom is excluded from an atom in Ra¹ and Ra², which is bonded to the nitrogen atom in the formula; Ra³ is an aliphatic hydrocarbon group or a hydrogen atom; and Ra⁴ is an aliphatic hydrocarbon group which may be substituted with a fluorine atom

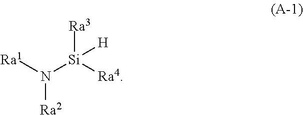

### BACKGROUND OF THE INVENTION

### Field of the Invention

The present invention relates to a surface treatment agent and a surface treatment method.

Priority is claimed on Japanese Patent Application No. 2019-221093, filed on Dec. 6, 2019, the content of which is incorporated herein by reference.

### Description of Related Art

In recent years, tendencies of high integration and miniaturization of a semiconductor device have increased, and microfabrication and achievement of a high aspect ratio of an inorganic pattern on a substrate are in progress. On the other hand, a problem of so-called pattern collapse may arise. This pattern collapse is a phenomenon in which when forming a number of inorganic patterns in parallel on a substrate, adjacent patterns are brought close to each other such that they lean on each other, which causes breakage or separation of the patterns from a base portion in some cases. Such pattern collapse causes decrease in the product yield and reliability.

It is known that this pattern collapse occurs due to surface tension of a washing liquid when the washing liquid dries in washing treatment after the pattern formation. That is, when the washing liquid is removed in the drying process, a stress acts between the patterns based on the surface tension of the washing liquid to cause pattern collapse.

From such a background, application of drug solutions for forming a protective film as disclosed in Japanese Unexamined Patent Application, First Publication No.

2016-66785 and Japanese Unexamined Patent Application, First Publication No. 2012-033873 has been proposed. According to the drug solutions disclosed in the literature, it is possible to impart water repellency to the surface of a concave-convex pattern. As a result, it is supposed that the pattern collapse can be suppressed.

Although different from the pattern collapse, water repellency (silylation) is imparted to the surface of a substrate using a silylating agent such as hexamethyldisilazane (HMDS) (for example, refer to [Background of the Invention] of Published Japanese Translation No. H11-511900 of the PCT International Publication) in order to prevent partial loss of a resin pattern due to a developer by improving adhesiveness between the resin pattern, which becomes an etching mask, and the substrate.

### REFERENCE LIST

### Patent Literature

[Patent Literature 1] Japanese Unexamined Patent Application, First Publication No. 2016-66785
[Patent Literature 2] Japanese Unexamined Patent Application, First Publication No. 2012-033873
[Patent Literature 3] Published Japanese Translation No. H11-511900 of the PCT International Publication

### SUMMARY OF THE INVENTION

Microfabrication and achievement of a high aspect ratio of an inorganic pattern on a substrate are in progress, and pattern collapse during cleaning and drying is becoming more likely to occur. On the other hand, even in a case where the pattern surface or the substrate surface is subjected to water repellency treatment with the conventional surface treatment agent as described above, the pattern collapse may not be sufficiently suppressed.

Accordingly, there is a demand for a surface treatment agent capable of more effectively suppressing pattern collapse. In addition, since it is necessary to remove the surface treatment agent after the washing treatment, the surface treatment agent needs to be easily removed.

The present invention has been made in consideration of the above circumstances, and an object of the present invention is to provide a surface treatment agent that is excellent in the effect of suppressing pattern collapse and also excellent in the removability from an object to be treated, and a surface treatment method.

In order to achieve the above-described object, the present invention adopted the following configurations.

The first aspect of the present invention is a surface treatment agent containing a silylating agent (A) and a solvent (S), in which the silylating agent (A) contains a compound (A1) represented by General Formula (A-1).

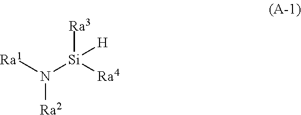

[In the formula, Ra¹ is a monovalent organic group having 1 to 10 carbon atoms or a hydrogen atom. Ra² is a monovalent organic group having 1 to 10 carbon atoms. Ra¹ and Ra² may be bonded to each other to form a ring. However, a Si atom is excluded from an atom in Ra¹ and Ra², which is bonded to a nitrogen atom in the formula. Ra³ is an aliphatic hydrocarbon group having 1 to 4 carbon atoms which may be substituted with a fluorine atom or a hydrogen atom. Ra⁴ is an aliphatic hydrocarbon group having 1 to 4 carbon atoms, which may be substituted with a fluorine atom.]

The second aspect of the present invention is a surface treatment method including subjecting an object to be treated to surface treatment using the surface treatment agent.

According to the present invention, a surface treatment agent that is excellent in the effect of suppressing pattern collapse and also excellent in the removability from an object to be treated, and a surface treatment method can be provided.

### DETAILED DESCRIPTION OF THE INVENTION

(Surface Treatment Agent)

A surface treatment agent according to the present embodiment contains a silylating agent (A) and a solvent (S).

The surface treatment agent according to the present embodiment is used, for example, for treating a surface of a semiconductor substrate having a pattern.

<Silylating Agent (A)>

The silylating agent (A) (hereinafter, also referred to as a “component (A)”) is a component for silylating the surface of an object to be treated (for example, a semiconductor substrate) to improve the water repellency of the surface of the object to be treated (for example, a semiconductor substrate).

The silylating agent (A) in the surface treatment agent according to the present embodiment contains a compound (A1) (hereinafter, also referred to as a “component (A1)”) represented by General Formula (A-1).

<<Compound (A1)>>

The compound (A1) is a compound represented by General Formula (A-1).

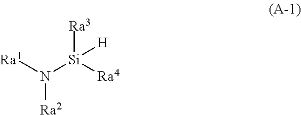

[In the formula, Ra¹ is a monovalent organic group having 1 to 10 carbon atoms or a hydrogen atom. Ra² is a monovalent organic group having 1 to 10 carbon atoms. Ra¹ and Ra² may be bonded to each other to form a ring. However, a Si atom is excluded from an atom in Ra¹ and Ra², which is bonded to a nitrogen atom in the formula. Ra³ is an aliphatic hydrocarbon group having 1 to 4 carbon atoms which may be substituted with a fluorine atom or a hydrogen atom. Ra⁴ is an aliphatic hydrocarbon group having 1 to 4 carbon atoms, which may be substituted with a fluorine atom.]

[In General Formula (A-1), Ra¹ is a monovalent organic group having 1 to 10 carbon atoms or a hydrogen atom. Examples of the monovalent organic group having 1 to 10 carbon atoms include a monovalent hydrocarbon group which may have a substituent. In a case where “may have a substituent” is described, both of a case where a hydrogen atom (—H) is substituted with a monovalent group and a case where a methylene (—CH₂—) group is substituted with a divalent group are included. Examples of the monovalent substituent include a carboxy group, a hydroxy group, an amino group, a sulfo group, a halogen atom, an alkoxy group, and an alkyloxycarbonyl group.

Examples of the divalent substituent include —O—, —C(═O)—O—, —C(═O)—, —O—C(═O)—O—, —C(═O)—NH—, —NH—, —CH═N—, —CH═N—CH═, —NH—C(═NH)—, —S—, —S(═O)₂—, and —S(═O)₂—O—. In addition, H in the divalent substituent may be substituted with a substituent, for example, an alkyl group or an acyl group.

Examples of the monovalent hydrocarbon group include a linear or branched alkyl group, a linear or branched alkenyl group, and a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, a methyl group or an ethyl group is more preferable, and a methyl group is still more preferable.

The branched alkyl group has preferably 3 to 8 carbon atoms and more preferably 3 to 5 carbon atoms. Specific examples thereof include an isopropyl group, an isobutyl group, a tert-butyl group, an isopentyl group, a neopentyl group, a 1,1-diethylpropyl group, and a 2,2-dimethylbutyl group, and an isopropyl group is preferable.

The linear alkenyl group has preferably 2 to 10 carbon atoms, more preferably 2 to 5 carbon atoms, and still more preferably 2 or 4 carbon atoms. Specific examples thereof include a vinyl group, a propenyl group (allyl group), and a butynyl group.

Specific examples of the branched alkenyl group include a 1-methylvinyl group, a 1-methylpropenyl group, and a 2-methylpropenyl group.

The cyclic hydrocarbon group may be an aliphatic hydrocarbon group or an aromatic hydrocarbon group, and may be a polycyclic group or a monocyclic group.

The aliphatic hydrocarbon group which is a monocyclic group is preferably a group in which one hydrogen atom is removed from a monocycloalkane. The monocycloalkane preferably has 3 to 6 carbon atoms, and specific examples thereof include cyclopentane and cyclohexane.

The aliphatic hydrocarbon group which is a polycyclic group is preferably a group in which one hydrogen atom is removed from a polycycloalkane. The polycycloalkane is preferably a polycycloalkane having 7 to 10 carbon atoms and examples thereof include adamantane and norbornane.

The aromatic hydrocarbon group is a hydrocarbon group having at least one aromatic ring.

The aromatic ring is not particularly limited as long as it is a cyclic conjugated system having 4n+2π electrons, and specific examples thereof include an aromatic hydrocarbon ring such as benzene; and an aromatic heterocycle in which a part of carbon atoms constituting the aromatic hydrocarbon ring are substituted with a hetero atom. Examples of the hetero atom in the aromatic heterocycle include an oxygen atom, a sulfur atom, and a nitrogen atom. Specific examples of the aromatic heterocycle include a pyridine ring and a thiophene ring.

Specific examples of the aromatic hydrocarbon group include a group in which one hydrogen atom is removed from the aromatic hydrocarbon ring or the aromatic heterocycle (aryl group or heteroaryl group); a group in which one hydrogen atom is removed from an aromatic compound containing two or more aromatic rings (for example, thiophene); and a group in which one hydrogen atom of the aromatic hydrocarbon ring or the aromatic heterocycle is substituted with an alkylene group (for example, an arylalkyl group such as a benzyl group). The alkylene group bonded to the aromatic hydrocarbon ring or the aromatic heterocycle has preferably 1 to 4 carbon atoms, more preferably 1 to 2 carbon atoms, and particularly preferably 1 carbon atom.

[In General Formula (A-1), Ra² is a monovalent organic group having 1 to 10 carbon atoms. Examples of the monovalent organic group include the same group as Ra¹.

In a case where Ra¹ is a monovalent organic group having 1 to 10 carbon atoms, the atom bonded to the nitrogen atom in General Formula (A-1) in the organic group may be a hetero atom. However, there is no case where a Si atom is not bonded thereto. The same applies to Ra².

Ra¹ and Ra² may be bonded to each other to form a ring. Specific examples of the ring formed by bonding Ra¹ and Ra² to each other include the following ring structures. * indicates a bonding position to a Si atom in General Formula (A-1).

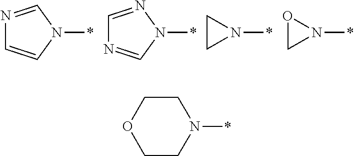

In General Formula (A-1), Ra¹ is preferably, among the above, a monovalent organic group having 1 to 10 carbon atoms. That is, in General Formula (A-1), both Ra¹ and Ra² are preferably a monovalent organic group having 1 to 10 carbon atoms. The monovalent organic group is more preferably a linear or branched alkyl group having 1 to 10 carbon atoms and still more preferably a linear alkyl group having 1 to 10 carbon atoms.

The linear alkyl group has preferably 1 to 5 carbon atoms, more preferably 1 to 4 carbon atoms, and still more preferably 1 or 2 carbon atoms. Specifically, a methyl group or an ethyl group is preferable and a methyl group is more preferable.

In General Formula (A-1), Ra³ is an aliphatic hydrocarbon group having 1 to 4 carbon atoms or a hydrogen atom which may be substituted with a fluorine atom.

In regard to the aliphatic hydrocarbon group having 1 to 4 carbon atoms, which may be substituted with a fluorine atom, the number of fluorine atoms is not particularly limited, and all the hydrogen atoms in the aliphatic hydrocarbon group may be substituted with fluorine atoms. Among them, the number of fluorine atoms is preferably 0 to 2, and it is more preferable that the hydrogen atoms in the aliphatic hydrocarbon group are not substituted with fluorine atoms.

Specific examples of the aliphatic hydrocarbon group having 1 to 4 carbon atoms as Ra³ include a group having 1 to 4 carbon atoms, among the groups exemplified as the linear or branched alkyl group and the linear or branched alkenyl group as Ra¹.

In General Formula (A-1), Ra⁴ is an aliphatic hydrocarbon group having 1 to 4 carbon atoms which may be substituted with a fluorine atom. Specific examples of Ra⁴ include the same group as the aliphatic hydrocarbon group having 1 to 4 carbon atoms as Ra³, which may be substituted with a fluorine atom.

In General Formula (A-1), Ra³ is preferably, among the above, an aliphatic hydrocarbon group having 1 to 4 carbon atoms, which may be substituted with a fluorine atom. That is, in General Formula (A-1), both of Ra³ and Ra⁴ are preferably aliphatic hydrocarbon groups having 1 to 4 carbon atoms, which may be substituted with a fluorine atom, both thereof are more preferably an aliphatic hydrocarbon group having 1 to 4 carbon atoms, both thereof are still more preferably a linear or branched alkyl group having 1 to 4 carbon atoms, and both thereof are particularly preferably a linear alkyl group having 1 to 4 carbon atoms.

The linear alkyl group has preferably 1 to 2 carbon atoms, specifically a methyl group or an ethyl group is more preferable, and a methyl group is still more preferable.

Among the above, the component (A1) is preferably a compound represented by General Formula (A-1-1).

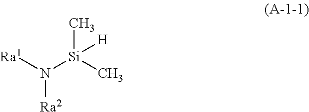

[In the formula, Ra¹ is a monovalent organic group having 1 to 10 carbon atoms or a hydrogen atom. Ra² is a monovalent organic group having 1 to 10 carbon atoms. Ra¹ and Ra² may be bonded to each other to form a ring. However, a Si atom is excluded from an atom in Ra¹ and Ra², which is bonded to a nitrogen atom in the formula.

In General Formula (A-1-1), Ra¹ and Ra² are respectively the same as Ra¹ and Ra² in General Formula (A-1).

Specific examples of the suitable component (A1) include N,N-(dimethylsilyl)dimethylamine, N,N-(dimethylsilyl)diethylamine, N,N-(dimethylsilyl)imidazole, N,N-(dimethylsilyl)triazole, N,N-(dimethylsilyl)aziridine, N,N-(dimethylsilyl)oxadilysin, and N,N-(dimethylsilyl)morpholine. Among them, N,N-(dimethylsilyl)dimethylamine or N,N-(dimethylsilyl)diethylamine is preferable, and N,N-(dimethylsilyl)dimethylamine is more preferable.

As the component (A1) in the surface treatment agent according to the present embodiment, one kind may be used alone, or two or more kinds may be used in combination.

The lower limit value of the content of the component (A1) according to the present embodiment is preferably 0.1% to 50% by mass, more preferably 0.5% to 30% by mass, still more preferably 1.0% to 20% by mass, and particularly preferably 5.0% to 10% by mass, with respect to the total amount of the surface treatment agent.

In a case where the content of the component (A1) is greater than or equal to the preferred lower limit value, it is possible to further improve the water repellency of the surface of the object to be treated.

On the other and, in a case where the content of the component (A) is lower than or equal to the upper limit value, it is easy to obtain a surface treatment agent having superior handleability.

The molar concentration of the component (A1) in the surface treatment agent according to the present embodiment is preferably 0.01 to 5.0 M and more preferably 0.1 to 1.0 M.

In a case where the molar concentration of the component (A1) is greater than or equal to the preferred lower limit value, it is possible to further improve the water repellency of the surface of the object to be treated.

In a case where the molar concentration of the component (A1) is lower than or equal to the upper limit value, it is easy to obtain a surface treatment agent having superior handleability.

The silylating agent (A) in the surface treatment agent according to the present embodiment may contain a silylating agent (A2) (hereinafter, also referred to as a “component (A2)”) other than the component (A1) described above.
Silylating agent (A2) other than component (A1)

The component (A2) is not particularly limited, but it is possible to use any silylating agent, other than the above-described component (A1), which is conventionally known in the related art. For example, silylating agents represented by General Formulae (1) to (3) can be used. In General Formulae (1) to (3), the alkyl group has 1 to 5 carbon atoms, the cycloalkyl group has 5 to 10 carbon atoms, the alkoxy group has 1 to 5 carbon atoms, and the heterocycloalkyl group has 5 to 10 carbon atoms.

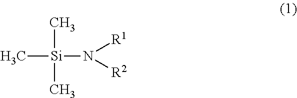

[In General Formula (1), R¹ represents a hydrogen atom or a saturated or unsaturated alkyl group, and R² represents a saturated or unsaturated alkyl group, a saturated or unsaturated cycloalkyl group, or a saturated or unsaturated heterocycloalkyl group. R¹ and R² may be bonded to each other to form a saturated or unsaturated heterocycloalkyl group having a nitrogen atom.]

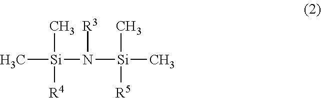

[In General Formula (2), R³ represents a hydrogen atom, a methyl group, a trimethylsilyl group, or a dimethylsilyl group, and R⁴, and R⁵ each independently represent a hydrogen atom, an alkyl group, or a vinyl group.]

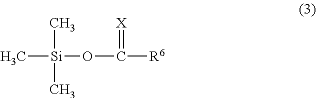

[In General Formula (3), X represents O, CHR⁷, CHOR⁷, CR⁷R⁷, or NR⁸, R⁶ and R⁷ each independently represent a hydrogen atom, a saturated or unsaturated alkyl group, a saturated or unsaturated cycloalkyl group, a trialkylsilyl group, a trialkylsiloxy group, an alkoxy group, a phenyl group, a phenethyl group, or an acetyl group, and R⁸ represents a hydrogen atom, an alkyl group, or a trialkylsilyl group.]

Examples of the silylating agent represented by General Formula (1) include N,N-dimethylaminotrimethylsilane (TMSDMA), N,N-diethylaminotrimethylsilane, t-butylaminotrimethylsilane, allylaminotrimethylsilane, trimethylsilylacetamide, trimethylsilylpiperidin, trimethylsilylimidazole, trimethylsilylmorpholine, 3-trimethylsilyl-2-oxazolidinone, trimethylsilylpyrazole, trimethylsilylpyrrolidin, 2-trimethylsilyl-1,2,3-triazole, and 1-trimethylsilyl-1,2,4-triazole.

Examples of the silylating agent represented by General Formula (2) include tetramethyldisilazane (TMDS), hexamethyldisilazane (HMDS), N-methylhexamethyldisilazane, 1,2-di-N-octyltetramethyldisilazane, 1,2-divinyltetramethyldisilazane, heptamethyldisilazane, nonamethyltrisilazane, and tris(dimethylsilyl)amine.

Examples of the silylating agent represented by General Formula (3) include trimethylsilyl acetate, trimethylsilyl propionate, trimethylsilyl butyrate, and trimethylsilyloxy-3-penten-2-one.

As the component (A2) in the surface treatment agent according to the present embodiment, one kind may be used alone, or two or more kinds may be used in combination.

The content of the component (A2) in the surface treatment agent according to the present embodiment is not particularly limited as long as the effects of the present invention are not impaired. For example, the content of the component (A2) is preferably 0.001% by mass or more and 30% by mass or less and more preferably 0.1% by mass or more and 15% by mass or less.

In the surface treatment agent according to the present embodiment, the proportion of the component (A1) is preferably 25% by mass or more, more preferably 50% by mass or more, and still more preferably 75% by mass, and may be 100% by mass or more, with respect to the total content of the component (A).

In a case where the proportion of the component (A1) in the component (A) is 25% by mass or more, the water repellency of the surface of the object to be treated can be further improved, and the removability of the surface treatment agent can be further improved.

<Solvent (S)>

The surface treatment agent according to the present embodiment contains a solvent (S) (hereinafter, also referred to as a “component (S)”). The component (S) is used for dissolving and mixing respective components to form a homogeneous solution. The component (S) may be any one as long as the respective components can be dissolved and mixed, and a component generally used as a solvent for the surface treatment agent can be used without particular limitation.

Examples of the component (S) include linear saturated aliphatic hydrocarbons such as n-hexane, n-heptane, n-octane, n-nonane, n-decane, n-undecane, n-dodecane, n-tridecane, n-tetradecane, n-pentadecane, n-hexadecane, n-heptadecane, n-octadecane, n-nonadecane, and n-icosane; branched saturated aliphatic hydrocarbons such as 2-methylpentane, 3-methylpentane, 2,2-dimethylbutane, 2,3-dimethylbutane, 2-methylhexane, 3-methylhexane, 2,3-dimethylpentane, 2,4-dimethylpentane, 2,2,3-trimethylpentane, 2,2,4-trimethylpentane, 3,4-diethylhexane, 2,6-dimethyloctane, 3,3-dimethyloctane, 3,5-dimethyloctane, 4,4-dimethyloctane, 3-ethyl-3-methylheptane, 2-methylnonane, 3-methylnonane, 4-methylnonane, 5-methylnonane, 2-methylundecane, 3-methylundecane, 2,2,4,6,6-pentamethylheptane, and 2,2,4,4,6,8,8-heptamethylnonane; cyclic saturated aliphatic hydrocarbons such as decalin, cyclohexane, methylcyclohexane, ethylcyclohexane, 1,2-dimethylcyclohexane, 1,3-dimethylcyclohexane, 1,4-dimethylcyclohexane, propylcyclohexane, isopropylcyclohexane, 1,2-methylethylcyclohexane, 1,3-methylethylcyclohexane, 1,4-methylethylcyclohexane, 1,2,3-trimethylcyclohexane, 1,2,4-trimethylcyclohexane, and 1,3,5-trimethylcyclohexane; sulfoxides such as dimethyl sulfoxide; sulfones such as dimethyl sulfone, diethyl sulfone, bis(2-hydroxyethyl) sulfone, and tetramethylene sulfone; amides such as N,N-dimethylformamide, N-methylformamide, N,N-dimethylacetamide, N-methylacetamide, and N,N-diethylacetamide; lactams such as N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; other ethers such as dimethylglycol, dimethyldiglycol, dimethyltriglycol, methylethyl diglycol, diethylglycol, diethylene glycol dimethyl ether, diethylene glycol methyl ethyl ether, diethylene glycol diethyl ether, triethylene glycol dimethyl ether, tetraethylene glycol dimethyl ether, and propylene glycol monomethyl ether; (poly)alkylene glycol monoalkyl ether acetates such as ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, propylene glycol monomethyl ether acetate, and propylene glycol monoethyl ether acetate; other esters such as methyl 2-hydroxypropionate, ethyl 2-hydroxypropionate, ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxy acetate, ethyl hydroxy acetate, methyl 2-hydroxy-3-methylbutanoate, 3-methoxybutyl acetate, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl acetate, n-hexyl acetate, n-heptyl acetate, n-octyl acetate, n-pentyl formate, isopentyl acetate, n-butyl propionate, ethyl butyrate, n-propyl butyrate, isopropyl butyrate, n-butyl butyrate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate, propylene glycol diacetate, and propylene carbonate; ketones such as methyl ethyl ketone, cyclohexanone, 2-heptanone, and 3-heptanone; lactones such as β-propiolactone, γ-butyrolactone, and δ-pentyrolactone; aromatic hydrocarbons such as benzene, toluene, xylene, 1,3,5-trimethylbenzene, and naphthalene; and terpenes such as p-menthane, diphenylmenthane, limonene, terpinene, bornane, norbornane, and pinane.

The content of the component (S) in the surface treatment agent according to the present embodiment is preferably 50% to 99.9% by mass, more preferably 70% to 98% by mass, and still more preferably 80% to 96% by mass, with respect to the total amount of the surface treatment agent.

<Other Components>

The surface treatment agent according to the present embodiment can contain other components other than the above-described components as long as the effects of the present invention are not impaired. Examples of other components include pH adjusters such as an acid and a base, and a surfactant.

<<Surfactant>>

Examples of the surfactant include a fluorine-based surfactant and a silicone-based surfactant.

Specific examples of the fluorine-based surfactant include commercially available fluorine-based surfactants such as BM-1000 and BM-1100 (all are manufactured by BM Chemie), MEGAFACE F142D, MEGAFACE F172, MEGAFACE F173, and MEGAFACE F183 (all are manufactured by DIC CORPORATION), FLUORAD FC-135, FLUORAD FC-170C, FLUORAD FC-430, and FLUORAD FC-431 (all are manufactured by Sumitomo 3M Limited), SURFLON S-112, SURFLON S-113, SURFLON S-131, SURFLON S-141, and SURFLON S-145 (all are manufactured by Asahi Glass Co., Ltd.), and SH-28PA, SH-190, SH-193, SZ-6032, and SF-8428 (all are manufactured by Toray Silicone Co., Ltd.).

As specific examples of the silicone-based surfactant, it is possible to preferably use an unmodified silicone-based surfactant, a polyether-modified silicone-based surfactant, a polyester-modified silicone-based surfactant, an alkyl-modified silicone-based surfactant, an aralkyl-modified silicone-based surfactant, and a reactive silicone-based surfactant.

A commercially available silicone-based surfactant can be used as the silicone-based surfactant. Specific examples of the commercially available silicone-based surfactant include PAINTAD M (manufactured by Dow Corning Toray Co., Ltd.), TOPEKA K1000, TOPEKA K2000, and TOPEKA K5000 (all are manufactured by Takachiho Industrial Co. Ltd.), XL-121 (a polyether-modified silicone-based surfactant, manufactured by Clariant), and BYK-310 (a polyester-modified silicone-based surfactant, manufactured by BYK Chemie).

In a case where the surface treatment agent according to the present embodiment contains a surfactant, one kind of surfactant may be used alone, or two or more kinds thereof may be used in combination.

The content of the surfactant in the surface treatment agent according to the present embodiment is not particularly limited as long as the effects of the present invention are not impaired. For example, the content of the surfactant is preferably 0.001% by mass or more and 10% by mass or less.

Since the surface treatment agent according to the present embodiment described above contains the component (A1) as a silylating agent, the water repellency of the surface of the object to be treated can be further improved, and the effect of suppressing pattern collapse can be further improved. In addition, since the component (A1) can be easily removed by heating, the surface treatment agent according to the present embodiment is also excellent in removability from the object to be treated.

The surface treatment agent according to the present embodiment is a surface treatment agent useful for treating a surface of a semiconductor substrate having a pattern.

(Surface Treatment Method)

The surface treatment method according to the present embodiment is a surface treatment method in which surface treatment of an object to be treated is performed using the above-described surface treatment agent.

Representative examples of the purpose of the surface treatment includes imparting water repellency to the surface having an inorganic pattern formed on the object to be treated to prevent pattern collapse in the washing treatment.

The surface treatment method according to the present embodiment has a water repellency treatment step of imparting water repellency (silylation) to the surface of the object to be treated.

<Water Repellency Treatment Step>

Examples of the water repellency treatment step in the present embodiment include a method of applying the above-described surface treatment agent onto the surface of the object to be treated.

Examples of the method for applying a surface treatment agent to the surface of an object to be treated include a spray method, a spin coating method, and an immersion method. The time for applying the surface treatment agent to the surface of the object to be treated is not particularly limited, and examples thereof include 1 second to 5 minutes.

Regarding the water repellency of the surface of the object to be treated, the contact angle of water with respect to the surface of the object to be treated is preferably 40° to 120°, more preferably 70° to 110°, and still more preferably 90° to 110° after the surface treatment.

A device used in the water repellency treatment step is not particularly limited as long as the device can apply a surface treatment agent onto the object to be treated. Examples of the device include a device that can apply a surface treatment agent to the object to be treated, with a spray method, a spin coating method, an immersion method, or the like.

Examples of the “object to be treated” to be subjected to surface treatment include a substrate used for producing a semiconductor device. Examples thereof include a silicon (Si) substrate, a silicon nitride (SiN) substrate, a silicon oxide film (Ox) substrate, a silicon carbide (SiC) substrate, a tungsten (W) substrate, a tungsten carbide (WC) substrate, a cobalt (Co) substrate, a titanium nitride (TiN) substrate, a tantalum nitride (TaN) substrate, a germanium (Ge) substrate, a silicon germanium (SiGe) substrate, an aluminum (Al) substrate, a nickel (Ni) substrate, a titanium (Ti) substrate, a ruthenium (Ru) substrate, and a copper (Cu) substrate.

Taking a silicon (Si) substrate as an example for description, a silicon oxide film such as a natural oxide film, a thermal oxide film, and a vapor-phase synthetic film (such as a CVD film) may be formed on the surface of the substrate, or a pattern may be formed on the silicon oxide film.

Examples of the “surface” include a surface of an inorganic pattern provided on a substrate and a surface of an unpatterned inorganic layer in addition to the surface of the substrate itself.

Examples of the inorganic pattern provided on the substrate include an inorganic pattern formed by producing an etching mask on a surface of an inorganic layer present on the substrate with a photoresist method and then performing etching treatment. Examples of the inorganic layer include, in addition to the substrate itself, a layer made of an oxide of an element constituting the substrate and a layer made of an inorganic substance, for example, silicon nitride, titanium nitride, and tungsten, which are formed on the surface of a substrate. Such an inorganic layer is not particularly limited. Examples thereof include an inorganic layer formed in the process of manufacturing a semiconductor device.

The shape of the pattern is not particularly limited and can be, for example, a pattern shape generally formed in a semiconductor manufacturing step. The pattern shape may be a line pattern, a hole pattern, or a pattern including a plurality of pillars. The pattern shape is preferably a pattern including a plurality of pillars. The shape of the pillar is not particularly limited. Examples thereof include a cylindrical shape and a polygonal prism shape (such as a square prism shape).

[Optional Step]

In addition to the water repellency treatment step described above, the surface treatment method according to the present embodiment may have steps such as a washing step, a rinsing step, and a drying step.

An example of one embodiment of the surface treatment method according to the present embodiment is a surface treatment method having a washing step of washing the surface of the object to be treated; water repellency treatment step of imparting water repellency (silylation) to the surface of the object to be treated, with the above-described surface treatment agent; a rinsing step of rinsing the surface of the object to be treated, to which water repellency has been imparted, with a rinsing liquid; and a drying step of drying the rinsed object to be treated.

<<Washing Step>>

The washing step is a step of previously washing the surface of an object to be treated.

The washing method is not particularly limited. Examples of the method for washing a semiconductor substrate includes a conventionally known RCA washing method. In the RCA washing method, first, a semiconductor substrate is immersed in an SC-1 solution of hydrogen peroxide and ammonium hydroxide to remove fine particles and an organic substance from the semiconductor substrate. Subsequently, the semiconductor substrate is immersed in an aqueous hydrogen fluoride solution to remove the natural oxide film on the surface of the substrate. Thereafter, the semiconductor substrate is immersed in an acidic solution of an SC-2 solution of hydrogen peroxide and diluted hydrochloric acid to remove alkali ions or metal impurities which are insoluble in the SC-1 solution.

<<Rinsing Step>>

The rinsing step is a step of rinsing the surface of the object to be treated, to which water repellency has been imparted (silylated), with a rinsing liquid.

In the rinsing step, the surface of the object to be treated, to which water repellency has been imparted (silylated), is rinsed with a rinsing liquid to be described below. The rinsing method is not particularly limited, and a method generally used for washing a substrate in a semiconductor manufacturing step can be employed. Examples of such a method include a method for immersing an object to be treated in a rinsing liquid, a method for bringing steam of a rinsing liquid into contact with an object to be treated, and a method for supplying a rinsing liquid to an object to be treated while spinning the object to be treated. Among them, a method for supplying a rinsing liquid to an object to be treated while spinning the object to be treated is preferable as the rinsing method. In the method described above, the rotational speed of the spinning is, for example, 100 rpm to 5,000 rpm.

Rinsing Liquid

The rinsing liquid used in the rinsing step is not particularly limited, and a liquid generally used in a step of rinsing a semiconductor substrate can be used. Examples of the rinsing liquid include a liquid containing a solvent. Examples of the solvent include the same solvent as the above-described solvent (S) and an alcohol-based solvent such as isopropyl alcohol and 1-hexanol.

The rinsing liquid may contain water instead of the solvent or together with the solvent.

The rinsing liquid may contain a conventionally known additive and the like. Examples of the conventionally known additive include a fluorine-based surfactant and a silicone-based surfactant. Examples of the fluorine-based surfactant and the silicone-based surfactant include the same surfactants as the fluorine-based surfactant and the silicone-based surfactant described in the surface treatment agent described above.

<<Drying Step>>

The drying step is a step of drying an object to be treated. It is possible to efficiently remove a rinsing liquid remaining on an object to be treated after the rinsing step by performing the drying step.

The method for drying an object to be treated is not particularly limited, and conventionally known methods such as spin drying, heat drying, warm air drying, and vacuum drying can be used. Suitable examples thereof include spin drying under the blowing of inert gas (nitrogen gas or the like).

Since the surface treatment method according to the present embodiment described above uses the surface treatment agent of the embodiment described above, it is excellent in the effect of suppressing pattern collapse.

The surface treatment method according to the present embodiment is a surface treatment method useful for treating a surface of a semiconductor substrate having a pattern.

### EXAMPLES

Hereinafter, the present invention will be described in more detail based on Examples, but the present invention is not limited to these Examples.

<Preparation of Surface Treatment Agent>

### Example 1, Comparative Examples 1 to 3

A surface treatment agent of each example was prepared by mixing respective components shown in Table 1 with each other. The surface treatment agent of each example was prepared so that the molar concentration of the component (A) in the surface treatment agent of each example was 0.62 M.

TABLE 1

| | Component (A) | | | | |
|---|---|---|---|---|---|
| | Component (A1) | | Component (A2) | Component (S) | |
| Example 1 | (A1)-1 | [6.87] | — | (S)-1 | [93.13] |

| | | | | | |
|---|---|---|---|---|---|
| Comparative | — | (A2)-1 | [7.80] | (S)-1 | [92.2] |
| Example 1 | | | | | |
| Comparative | — | (A2)-2 | [8.87] | (S)-1 | [91.13] |
| Example 2 | | | | | |
| Comparative | — | (A2)-3 | [10.77] | (S)-1 | [89.23] |
| Example 3 | | | | | |

In Table 1, each abbreviation has the following meaning. The numerical values in the parentheses represent blending amount (% by mass).

(A1)-1: N,N-(dimethylsilyl)dimethylamine (DMSDMA)

(A2)-1: N,N-dimethylaminotrimethylsilane (TMSDMA)

(A2)-2: tetramethyldisilazane (TMDS)

(A2)-3: hexamethyldisilazane (HMDS)

(S)-1: propylene glycol monomethyl ether acetate (PGMEA)

<Surface Treatment Method 1>

As the object to be treated, a substrate of which the surface material was SiO₂ was used. After washing the substrate with a 0.5% aqueous hydrogen fluoride solution for 1 minute, the substrate was immersed in the surface treatment agent of each example at room temperature (25° C.) for 1 minute. Then, the surface of the substrate was rinsed with isopropyl alcohol and dried by nitrogen blowing.

[Evaluation of Water Repellency]

A surface of a substrate was surface-treated by <Surface treatment method 1> described above, a pure water droplet (2.0 μL) was dropped on the surface of the substrate using Dropmaster 700 (manufactured by Kyowa Interface Science Co., Ltd), and the contact angle of water with respect to the substrate surface 2 seconds after the dropping was measured. The larger the contact angle is, the higher the water repellency is. The results are shown in Table 2.

[Evaluation of Removability]

The substrate evaluated by [Evaluation of water repellency] described above was heat-treated for 20 minutes on a hot plate heated to 300° C. Thereafter, a pure water droplet (2.0 μL) was dropped on the surface of the substrate using Dropmaster 700 (manufactured by Kyowa Interface Science Co., Ltd), and the contact angle of water 2 seconds after the dropping was measured. The difference between this contact angle and the contact angle measured in [Evaluation of water repellency] described above was obtained, and the removability of the surface treatment agent of each example from the substrate was evaluated based on the following criteria. The results are shown in Table 2.

The water repellency of the surface treatment agent of Comparative Example 3 was very low, and thus the removability thereof was not evaluated.

<Evaluation Criteria>

A: The contact angle decreased by 4° or more due to the heat treatment.

B: The decrease in contact angle due to the heat treatment was less than 4°.

<Surface Treatment Method 2>

As the object to be treated, silicon pattern chips (1 cm×1 cm) having a pillar structure were used. The chips were immersed in the surface treatment agents of each example at room temperature (25° C.) for 1 minute. Then, the surface of the chip was rinsed with isopropyl alcohol and dried by nitrogen blowing.

[Evaluation of Pattern Collapse Suppressibility]

According to <Surface treatment method 2> described above, the surface of the surface-treated chip was observed by SEM, the occurrence rate of the pattern collapse of the chip was calculated, and the suppressibility of pattern collapse was evaluated based on the following criteria. The results are shown in Table 2.

In a case where the chip was not surface-treated with the surface treatment agent of each example, the surface of the chips was rinsed with isopropyl alcohol, and the rinsed chip was dried by nitrogen blowing, the occurrence rate of pattern collapse of the chip was 100%.

<Evaluation Criteria>

A: The occurrence rate of pattern collapse was less than 10%.

B: The occurrence rate of pattern collapse was 10% or more.

TABLE 2

| | Water | | Suppressibility of |
|---|---|---|---|
| | repellency | Removability | pattern collapse |
| Example 1 | 99° | A | A |
| Comparative | 85° | B | B |
| Example 1 | | | |
| Comparative | 80° | B | B |
| Example 2 | | | |
| Comparative | 10° | — | B |
| Example 3 | | | |

From the results shown in Table 2, it can be confirmed that the surface treatment agent of Example provides a large contact angle of water and high water repellency as compared with the surface treatment agents of Comparative Examples. In addition, it can be confirmed that the surface treatment agent of Example provides a large change in the contact angle of water and excellent removability after the heat treatment, as compared with the surface treatment agents of Comparative Examples. Further, it can be confirmed that in the chip surface-treated with the surface treatment agent of Example, the occurrence rate of pattern collapse after rinsing and drying is less than 10%, and the suppressibility of pattern collapse is excellent.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A surface treatment agent comprising:
a silylating agent (A); and
a solvent (S),
wherein the silylating agent (A) contains a compound (A1) represented by General Formula (A-1): 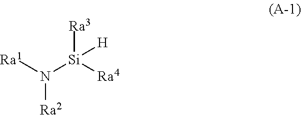
wherein Ra¹ is a hydrogen atom or a monovalent organic group having 1 to 10 carbon atoms; Ra² is a monovalent organic group having 1 to 10 carbon atoms; Ra¹ and Ra² may be bonded to each other to form a ring, provided that a Si atom is excluded from an atom in Ra¹ and Ra², which is bonded to the nitrogen atom in the formula; Ra³ is a hydrogen tom or an aliphatic hydrocarbon group having 1 to 4 carbon atoms which may be substituted with a fluorine atom; and Ra⁴ is an aliphatic hydrocarbon group having 1 to 4 carbon atoms, which may be substituted with a fluorine atom.

2. The surface treatment agent according to claim 1, wherein the surface treatment agent is used for treating a surface of a semiconductor substrate having a pattern.

3. The surface treatment agent according to claim 1, wherein the compound (A1) is a compound represented by General Formula (A-1-1), 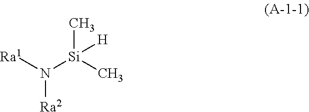
wherein Ra¹ is a hydrogen atom or a monovalent organic group having 1 to 10 carbon atoms; Ra² is a monovalent organic group having 1 to 10 carbon atoms; and Ra¹ and Ra² may be bonded to each other to form a ring, provided that a Si atom is excluded from an atom in Ra¹ and Ra², which is bonded to the nitrogen atom in the formula.

4. The surface treatment agent according to claim 1, wherein the compound (A1) is at least one compound selected from the group consisting of N,N-(dimethylsilyl)dimethylamine, N,N-(dimethylsilyl)diethylamine, N,N-(dimethylsilyl)imidazole, N,N-(dimethylsilyl)triazole, N,N-(dimethylsilyl)aziridine, N,N-(dimethylsilyl)oxadilysin, and N,N-(dimethylsilyl)morpholine.

5. A surface treatment method comprising subjecting an object to be treated to surface treatment using the surface treatment agent according to claim 1.

6. The surface treatment method according to claim 5, wherein the object to be treated comprises a surface of a semiconductor substrate having a pattern.
